(19) United States
(12) Patent Application Publication
(10) Pub. No.: US 2006/0007650 A1
(43) Pub. Date: Jan. 12, 2006

(54) Computer

(76) Inventor: Woo-jung Shim, Anyong-si (KR)

Correspondence Address: STANZIONE & KIM, LLP, 919 18TH STREET, N.W., SUITE 440, WASHINGTON, DC, 20006, US

(21) Appl. No.: 11/151,348

(22) Filed: Jun. 14, 2005

(30) Foreign Application Priority Data
Jul. 9, 2004 (KR) 2004-53512

(51) Int. Cl. G06F 1/16; H05K 5/00; H05K 7/00

(52) U.S. Cl. 361/685

(57) ABSTRACT

A computer includes a main casing to accommodate a plurality of hardware components, a supporting bracket provided in the main casing and having an entrance opening to accommodate and support a first peripheral unit, and a clip unit coupled to the supporting bracket to cover at least a region of the entrance opening and to contact a second peripheral unit placed above the first peripheral unit in the supporting bracket to resiliently support the second peripheral unit. Thus the computer, allows an additional peripheral unit to be easily mountable to and detachable from the main casing.

### CROSS-REFERENCE TO RELATED APPLICATIONS

This application claims the benefit under 35 U.S.C. § 119 of Korean Patent Application No. 2004-53512, filed on Jul. 9, 2004, in the Korean Intellectual Property Office, the disclosure of which is incorporated herein in its entirety by reference.

### BACKGROUND OF THE INVENTION

1. Field of the Invention

The present general inventive concept relates to a computer, and more particularly, to a computer having an improved structure of supporting an additional peripheral unit.

2. Description of the Related Art

As shown in FIG. 1, a conventional computer 101 comprises a main frame 103 forming an accommodating space and formed with an opening, and a cover (not shown) opening and closing the opening of the main frame 103.

In the main frame 103 are accommodated hardware components, such as a main board mounted with a central processing unit (CPU), a random access memory (RAM), various expanded cards or the like, a floppy disk drive (FDD), a compact disk (CD)- read only memory (ROM), and a hard disk drive (HDD), which are connected to the main board through cables.

Among the hardware components, first and second hard disk drives 110a and 110b are electronically connected to the main board, and store data from the CPU. Here, the first and second hard disk drives 110a and 110b are accommodated in a hard disk drive casing 120, and mounted to the main frame 103.

The conventional hard disk drive casing 120 is shaped like a box and made of steel material to accommodate the first and second hard disk drives 110a and 110b. Generally, the conventional hard disk drive casing 120 has a space large enough to accommodate the first and second hard disk drives 110a and 110b.

The hard disk drive casing 120 has opposite walls formed with a plurality of screw through holes 121 to be coupled with screw holes 111a and 111b of the first and second hard disk drives 110a and 110b by screws 108.

Further, the hard disk drive casing 120 has a pair of skirt portions 122 extending from opposite ends and bent outwardly, and each skirt portion 122 is formed with a plurality of mounting holes 123 on a surface thereof to be coupled with mount holes 107 formed on the main frame 103 by screws 109.

With the above-described configuration of the conventional computer 101, the first and second hard disk drives 110a and 110b are installed in the main frame 103 as follows.

First, the first and second hard disk drives 110a and 110b are inserted in the hard disk drive casing 120, and then the screws 108 are fastened into the screw holes 111a and 111b of the first and second hard disk drives 110a and 110b via the screw through holes 121 of the hard disk drive casing 120, so that the first and second hard disk drives 110a and 110b are accommodated in and supported by the hard disk drive casing 120.

Then, the hard disk drive casing 120 accommodating the first and second hard disk drives 110a and 110b therein is placed in the main frame 103, and the screws 109 are fastened into the mount holes 107 via the mounting holes 123 formed on the skirt portions 122 of the hard disk drive casing 120, so that the hard disk drive casing 120 is installed in the main frame 103.

However, in the conventional computer 101, when a user wants to additionally mount the second hard disk drive 110b into the hard disk driving casing in the state in which only the first hard disk drive 110a is mounted to the hard disk drive casing 120, the hard disk drive casing 120 must first be detached from the main frame 103. Then, the second hard disk drive 110b is laid on the first hard disk drive 110a, and the second hard disk drive 110b is fastened to the hard disk drive casing 120 by the screws 108. Then, the hard disk drive casing 120 accommodating the first and second hard disk drives 110a and 110b therein is installed into the main frame 103 again by the screws 109.

As described above, the screws 108 are necessarily used to additionally mount the second hard disk drive 110b to the hard disk drive casing 120, so that the mounting process is complicated. Further, to additionally mount the second hard disk drive 110b, the hard disk drive casing 120 must be detached from and installed again in the main casing 103, so that the mounting process is complicated and takes a considerable amount of time.

### SUMMARY OF THE INVENTION

Accordingly, the present general inventive concept provides a computer in which an additional peripheral unit is easily mountable to and detachable from a main casing.

Additional aspects of the present general inventive concept will be set forth in part in the description which follows and, in part, will be obvious from the description, or may be learned by practice of the general inventive concept.

The foregoing and/or other aspects of the present general inventive concept are achieved by providing a computer comprising a main casing to accommodate a plurality of hardware components, and further comprising a supporting bracket provided in the main casing and having an entrance opening to accommodate and support a first peripheral unit, and a clip unit coupled to the supporting bracket to cover at least a region of the entrance opening and to contact a second peripheral unit placed above the first peripheral unit in the supporting bracket to resiliently support the second peripheral unit.

The clip unit may comprise a resilient supporting portion to contact a top portion of the second peripheral unit at the entrance opening of the supporting bracket to resiliently support the second peripheral unit, and supporting legs extending from opposite sides of the resilient supporting portion and coupled to opposite walls of the supporting bracket, respectively.

The opposite walls of the supporting bracket may be formed with holding grooves, and the supporting legs may be formed with holding portions bent therefrom to couple with the holding grooves.

### BRIEF DESCRIPTION OF THE DRAWINGS

These and/or other aspects of the present general inventive concept will become apparent and more readily appreciated from the following description of the embodiments, taken in conjunction with the accompanying drawings of which:

FIG. 1 is an exploded perspective view of a conventional computer.

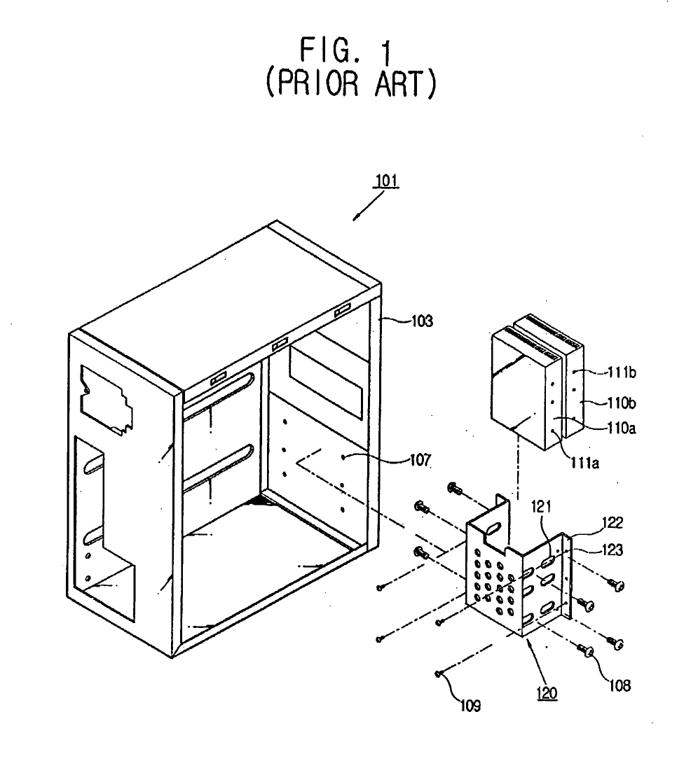

FIG. 2 is an exploded perspective view illustrating a computer according to an embodiment of the present general inventive concept;

FIG. 3 is a perspective view illustrating a hard disk drive assembly of the computer of FIG. 2;

FIG. 4 is a schematic section view illustrating the hard disk drive assembly of FIG. 3;

FIG. 5 is an exploded perspective view illustrating the hard disk drive assembly of FIG. 3;

FIG. 6 is a perspective view illustrating a first hard disk drive mounted to a supporting bracket according to an embodiment of the present general inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept while referring to the figures.

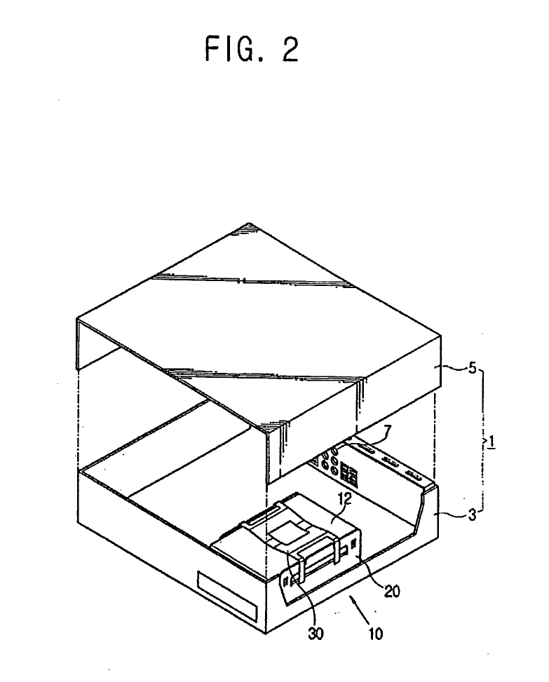

FIG. 2 illustrates a computer 1 according to an embodiment of the present general inventive concept. Referring to FIG. 2, the computer 1 comprises a plurality of hardware components, such as a hard disk drive assembly 10 or the like, a monitor (not shown) to display a picture based on a video signal received from the computer 1, and an input unit (not shown), such as a keyboard (not shown), a mouse (not shown), etc., to input information to the computer.

The computer 1 comprises a main casing 3 forming an accommodating space to accommodate the plurality of hardware components and having an opening and a cover 5 to open/close the opening of the main casing 3.

At a back portion of the main casing 3, a plurality of insertion holes 7 are formed, and at a front portion of the main casing 3, auxiliary memories, such as a compact disk drive, a floppy disk drive, etc., are exposed.

Inside the main casing 3, hardware components, such as a main board (not shown) mounted with a CPU, the hard disk drive assembly 10, etc, and a power supply (not shown) to supply power to the hardware components are mounted.

The hard disk drive assembly 10 is electronically connected to the main board and stores data from the CPU, and is mounted at an inside wall of the main casing 3, as illustrated in FIG. 2.

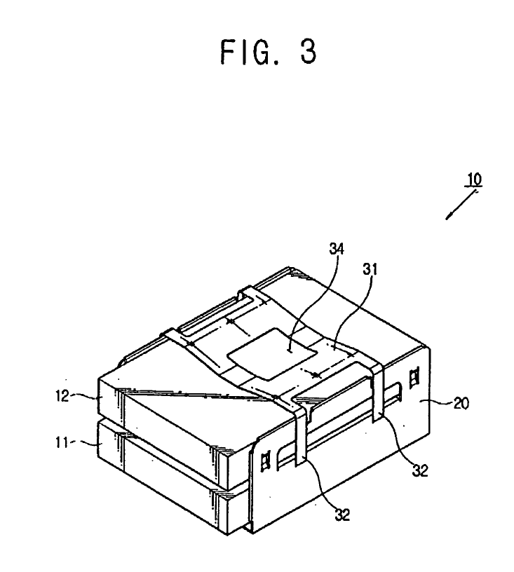

FIGS. 3-6 illustrate the hard disk drive assembly 10 of the computer 1. Referring to FIGS. 2-6, the hard disk drive assembly 10 comprises first and second hard disk drives 11 and 12 as first and second peripheral units, respectively, a supporting bracket 20 to accommodate the first and second hard disk drives 11 and 12 and support the first and second hard disk drives 11 and 12 at the inside wall of the main casing 3, and a clip unit 30 to support the second hard disk drive 12 with respect to the supporting bracket 20.

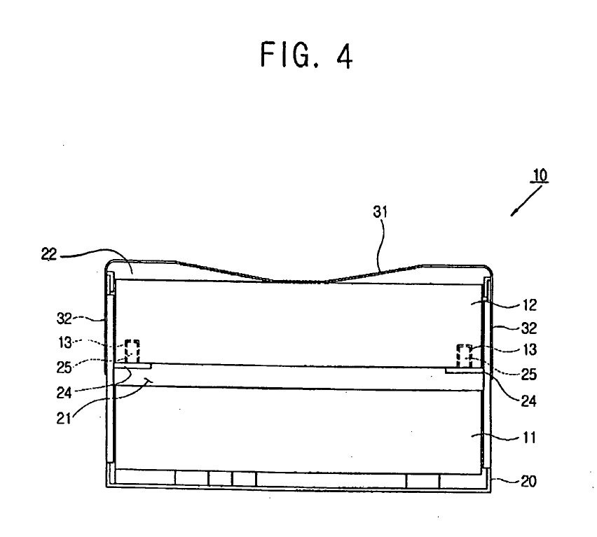

The second hard disk drive 12 is placed adjacent to or against the first hard disk drive 11 in the supporting bracket 20. The second hard disk drive 12 is formed with projection grooves 13 (FIG. 4) at a surface thereof to engage with projections 25 of the supporting bracket 20 (to be described later).

The supporting bracket 20 has a [symbol] -shaped section, and comprises a side opening as an entrance opening, a forward opening, and a backward opening. Further, the supporting bracket 20 forms first and second accommodating spaces 21 and 22. Here, the supporting bracket 20 is partitioned by supporting flanges 24 into the first and second accommodating spaces 21 and 22, wherein the supporting flanges 24 protrude in an inward direction from opposite sides of the supporting bracket 20 and partition an inner space of the supporting bracket 20 into the first and second accommodating spaces 21 and 22.

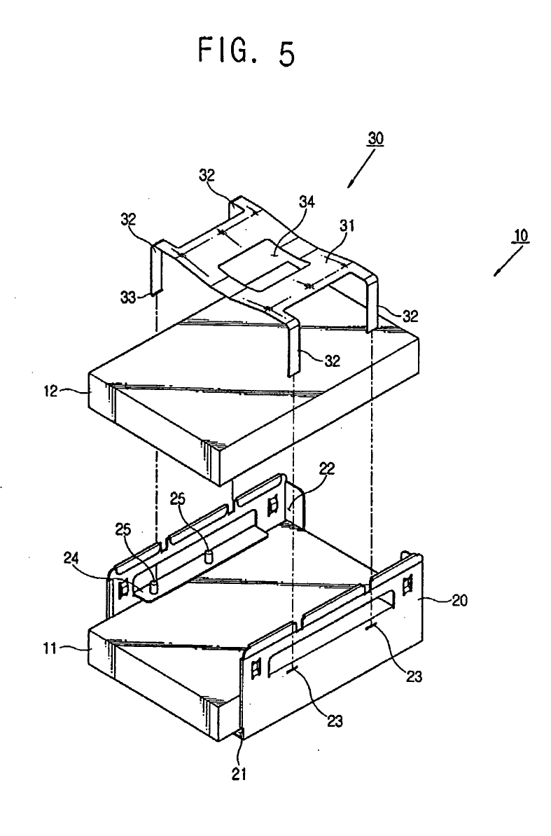

Outer walls of the supporting bracket 20 are formed with holding grooves 23 (see FIG. 5) to couple with the clip unit 30.

Each supporting flange 24 is formed with projections 25 protruding outwardly from a surface thereof to engage with the projection grooves 13, respectively, of the second hard disk drive 12.

Thus, when the second hard disk drive 12 is placed against the supporting flanges 24, the projections 25 are inserted into the respective projection grooves 13 of the second hard disk drive 12 and left and right sides of the second hard disk drive 12 are supported by the supporting flanges 24. That is, the engagement between the projection grooves 13 and the respective projections 25 prevents the second hard disk drive 12 from moving from side to side with respect to the supporting flanges 24.

As illustrated in FIG. 5, the clip unit 30 supports a side portion of the second hard disk drive 12 when another side of the second hard disk drive 12 is placed against the supporting flanges 24, and has an approximately [symbol] -shaped section opposite to the supporting bracket 20.

The clip unit 30 comprises a resilient supporting portion 31 to contact a side portion of the second hard disk drive 12 at the entrance opening of the supporting bracket 20, supporting legs 32 bending from opposite sides of the resilient supporting portion 31 to support a side portion of the second hard disk drive 12, and a holding portion 33 provided at each supporting leg 32 to couple with the holding grooves 23 of the supporting bracket 20.

The resilient supporting portion 31 can be formed with an approximately rectangular cut out portion 34 in a center portion thereof as illustrated in FIGS. 3 and 5, and gradually slopes from outer portions thereof toward the center portion in a same direction as the direction in which the supporting legs 32 bend.

As described above, the holding portion 33 of each supporting leg 32 couples with one of the holding grooves 23 of the supporting bracket 20, and the resilient supporting portion 31 is opened at the cut out portion 34 at the center portion and gradually slopes from the outer portions toward the center portion such that the resilient supporting portion 31 provides a pressing force to a side portion of the second hard disk drive 12. Thus, the clip unit 30 presses the second hard disk drive 12 and resiliently supports the second hard disk drive 12 with respect to the supporting bracket 20.

With the configuration as described above, a process of additionally mounting the second hard disk drive 12 to the supporting bracket 20 installed in the main casing 3 will be described below.

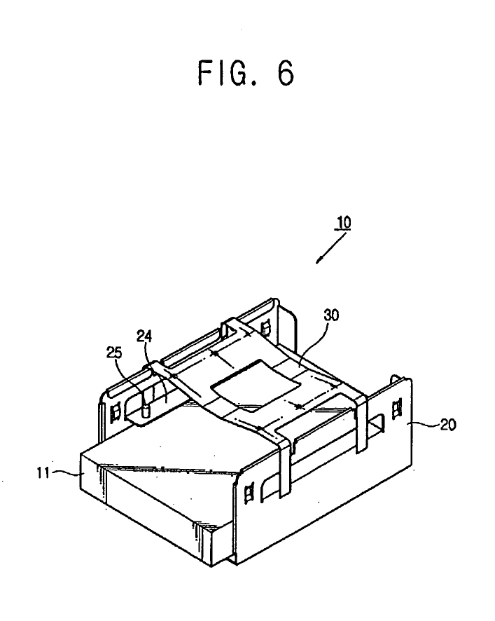

First, as illustrated in FIG. 6, the first hard disk drive 11 is accommodated in the first accommodating space 21 of the supporting bracket 20 installed in the main casing 3, and the clip unit 30 is coupled to the supporting bracket 20.

In this state, when the second hard disk drive 12 is additionally desired to expand the memory of the computer 1, the clip unit 30 allows the second hard disk drive 12 to be easily mountable into the supporting bracket 20 installed in the main casing 3.

That is, the holding portion 33 of the clip unit 30 is detached from the holding groove 23 of the supporting bracket 20, and then the second hard disk drive 12 is placed against the supporting flanges 24 of the supporting bracket 20. Thus, the first hard disk drive 11 is accommodated in the first accommodating space 21 of the supporting bracket 20, and the second hard disk drive 12 is accommodated in the second accommodated space 22 and disposed adjacent to the first hard disk drive 11.

The projections 25 formed at each supporting flange 24 are inserted into the projection grooves 13 of the second hard disk drive 12, thereby preventing the second hard disk drive 12 from moving from side to side.

Then, in the state in which the resilient supporting portion 31 of the clip unit 30 is in contact with a side portion of the second hard disk drive 12, the holding portion 33 formed at each supporting leg 31 of the clip unit 30 is inserted into the respective holding groove 23 of the supporting bracket 20 such that the second hard disk drive 12 is completely mounted to the supporting bracket 20, as illustrated in FIG. 3.

Here, while the supporting legs 32 are supported at the opposite sides of the supporting bracket 20, the resilient supporting portion 31 resiliently contacts a side portion of the second hard disk drive 12 such that the resilient supporting portion 31 presses the second hard disk drive 12 and resiliently supports the second hard disk drive 12.

According to the embodiment of the present general inventive concept described above, the second hard disk drive 12 is placed adjacent to the first hard disk drive 11 on the supporting flanges 24 of the supporting bracket 20 installed in the main casing 3, and then the clip unit 30 is coupled to the supporting bracket 20, thereby supporting the second hard disk drive 12.

As described above, peripheral units are illustrated as hard disk drives, but the present general inventive concept is not limited thereto. Alternatively, peripheral units may include various other hardware components, such as an optical disk drive (ODD), etc.

As described above, the second hard disk drive 12 is formed with the projection grooves 13, and the supporting flanges 24 are formed with the projections 25. Alternatively, the second hard disk drive may be formed with the projections, and the supporting flanges may be formed with the projection grooves.

As described above, the present general inventive concept provides a computer in which an additional peripheral unit is easily mountable to and detachable from a main casing without taking a considerable amount of time.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A computer comprising a main casing to accommodate a plurality of hardware components, and further comprising:
a supporting bracket provided in the main casing and having an entrance opening to accommodate and support a first peripheral unit; and
a clip unit coupled to the supporting bracket to cover at least a region of the entrance opening and to contact a second peripheral unit placed adjacent to the first peripheral unit in the supporting bracket to resiliently support the second peripheral unit.

2. The computer according to claim 1, wherein the clip unit comprises:
a resilient supporting portion to contact a top portion of the second peripheral unit at the entrance opening of the supporting bracket to resiliently support the second peripheral unit; and
supporting legs extending from opposite sides of the resilient supporting portion to couple to opposite walls of the supporting bracket, respectively.

3. The computer according to claim 2, wherein the opposite walls of the supporting bracket are formed with holding grooves, and the supporting legs are formed with holding portions bending therefrom to couple with the holding grooves.

4. The computer according to claim 1, wherein opposite inner walls of the supporting bracket are formed with supporting flanges to support a bottom portion of the second peripheral unit.

5. The computer according to claim 4, wherein one of a bottom portion of the second peripheral unit and a top portion of each supporting flange is formed with at least one projection extending therefrom, and the other one thereof is formed with at least one corresponding projection groove to engage with the corresponding projection.

6. A computer, comprising:
a main frame;
a bracket having a first surface connectable to an inner surface of the main frame and first and second side surfaces extending in a same direction with respect to each other from opposing ends of the first surface to accommodate two peripheral units within the main frame, the first peripheral unit being secured between the first surface and a first surface of dividers extending from each of the first and second side surfaces toward the other one of the first and second side surfaces, and the second peripheral unit securable one a second surface of each of the dividers; and
a clip unit to removably couple to each of outer surfaces of the first and second side surfaces to securely install and remove the second peripheral unit to the bracket without removing the bracket from the main frame.

7. The computer according to claim 6, wherein the clip unit comprises:
an upper plate to span an open portion of the bracket; and
supporting legs extending from the upper plate at opposite sides thereof to removably couple with the outer surfaces of the first and second side surfaces, respectively.

8. The computer according to claim 6, wherein each divider comprises one of projections and grooves to detachably couple with one of respective grooves and projections extending from a surface of the second peripheral unit.

9. The computer according to claim 6, wherein the clip unit comprises a resilient material.

10. A computer, comprising:
a first hard disk drive; and
a hard disk drive support assembly comprising:
a support bracket to support the first hard disk drive and to accommodate an additional hard disk drive or plurality of hard disk drives grouped together in a space adjacent to the first hard disk drive, and
a resilient clip unit attachable to opposite ends of the support bracket to provide a resilient force to an outermost one of the additional hard disk drives to support the additional hard disk drives, and detachable from at least one of the opposite ends of the support bracket to allow the additional hard disk drives to be added to or removed from the space adjacent to the first hard disk drive.

11. The computer according to claim 10, wherein the resilient clip unit comprises:
a resilient plate having a open center portion thereof that bends inward from opposite side portions thereof to press the outermost one of the additional hard disk drives; and
supporting legs extending from the opposite side portions of the resilient plate to detachably couple with walls of the supporting bracket.

12. The computer according to claim 11, wherein each supporting leg comprises a holding portion protruding therefrom, and the walls of the supporting bracket comprise supporting grooves to respectively accommodate the holding portions to couple the clip unit to the supporting bracket such that the clip unit is detachable from the supporting bracket by removing the holding portions from the supporting grooves.

13. The computer according to claim 10, wherein the supporting bracket comprises:
one or more pairs of supporting flanges, each formed on opposite inner surfaces of the supporting bracket to support the additional hard disk drives in the space adjacent to the first hard disk drive.

14. The computer according to claim 13, wherein each supporting flange comprises a coupling portion to detachably couple with an innermost one of the additional hard disk drives.

15. A peripheral unit supporting apparatus to support one or more peripheral units within a main frame of a computer, the peripheral unit supporting apparatus comprising:
a bracket comprising:
a first surface connectable within a main frame of a computer,
first and second side surfaces extending from opposite ends of the first surface in the same direction with respect to each other, and
dividers extending from each of the first and second side surfaces toward the other one of the first and second side surfaces to secure a first peripheral unit between a first surface of the dividers and the first surface of the bracket and to be connectable to a second peripheral unit at a second surface of the dividers; and
a detachable clip to removably couple to outer portions of the first and second side surfaces to secureably install and remove the second peripheral unit within the bracket.

16. The peripheral unit supporting apparatus according to claim 15, wherein each divider comprises either projections extending from the second surface thereof or grooves formed therein to detachably couple with either grooves formed in a surface of the second peripheral unit or projections extending from a surface of the second peripheral unit, respectively.

17. The peripheral unit supporting apparatus according to claim 15, wherein the detachable clip comprises legs extending from opposite ends thereof and having projections projecting from each of the legs to be inserted into grooves formed in the first and second side surfaces to removably secure the detachable clip to the bracket.
